(19) United States
(12) Patent Application Publication
(10) Pub. No.: US 2015/0179743 A1
(43) Pub. Date: Jun. 25, 2015

(54) Graphene as a Ge Surface Passivation Layer to Control Metal-Semiconductor Junction Resistivity

(71) Applicant: Intermolecular, Inc., San Jose, CA (US)

(72) Inventor: Sandip Niyogi, San Jose, CA (US)

(73) Assignee: Intermolecular, Inc., San Jose, CA (US)

(21) Appl. No.: 14/134,329

(22) Filed: Dec. 19, 2013

(51) Int. Cl. H01L 29/16; H01L 29/51; H01L 29/26; H01L 21/02; H01L 21/3205; H01L 29/49; H01L 29/45; H01L 29/161

(52) U.S. Cl. CPC H01L 29/1606; H01L 29/45; H01L 29/518; H01L 29/517; H01L 29/161; H01L 21/02532; H01L 21/02527; H01L 21/02546; H01L 21/0262; H01L 21/32051; H01L 29/4916; H01L 29/4966; H01L 29/26

(57) ABSTRACT

In some embodiments, a “channel last” device architecture is implemented wherein an amorphous carbon layer is formed between the channel and the source and drain layers. Subsequent heating of the structure allows the metal materials in the source and drain layers to convert the amorphous carbon materials into graphene. This forms an ohmic contact between the source and drain layers and the channel layers and lowers the contact resistance.

### TECHNICAL FIELD

The present disclosure relates generally to methods and apparatuses for processing using graphene in the manufacture of microelectronic devices.

### BACKGROUND

As feature sizes for semiconductor devices continue to decrease, manufacturers are increasingly building devices entirely on top of substrate materials so that all device components are explicitly fabricated and controlled for size and functional characteristics. The semiconductor material used for the device components may be different from that of the substrate. For example, a high-speed field effect transistor (FET) can be made using a doped germanium semiconductor deposited on a silicon wafer. The silicon wafer does not provide any device function beyond being a substrate support. All semiconductor elements can be deposited as doped germanium together with suitable contact electrodes, interface layers and the like.

A typical gate stack for a germanium transistor built on top of a silicon wafer includes many layers. A buffer layer is necessary between the silicon substrate material and the active germanium channel because there is a ˜4% lattice mismatch between germanium and silicon. One method used to build the buffer layer is to make a graded layer of a Si—Ge alloy having mostly silicon at the substrate and mostly germanium at the top interface of the layer. A typical buffer layer thickness is about 2 nm. A high-κ gate dielectric layer is formed above the channel, and a gate metal layer is formed on the gate dielectric layer. The high-κ gate dielectric may be an oxide such as an oxide of aluminum, dysprosium, gadolinium, hafnium, lanthanum, yttrium, zirconium, or combinations thereof. An interfacial layer is also typically used between the germanium channel and the gate dielectric to prevent atomic migration between the channel and the gate dielectric. Typical materials for the interfacial layer are various non-stoichiometric oxides of germanium, (e.g., GeOₓ where 1<x<4).

Many problems arise in fabricating working devices using the gate stack described above. Defects for the Si—Ge buffer layer can propagate into each layer preventing the formation of defect-free layers. The GeOₓ layer tends to be unstable. It is difficult to devise a process where device parameters can be independently controlled during fabrication.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, a “channel last” device architecture is implemented wherein an amorphous carbon layer is formed between the channel and the source and drain layers. Subsequent heating of the structure allows the metal materials in the source and drain layers to convert the amorphous carbon materials into graphene. This helps to form an ohmic contact between the source and drain layers and the channel layers and helps to lower the contact resistance.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a cross-sectional schematic diagram of a typical semiconductor device.

FIG. 2 illustrates a schematic diagram for plasma enhanced deposition according to some embodiments.

FIG. 3 illustrates a processing system enabling plasma surface treatment according to some embodiments.

FIG. 4 illustrates a cross-sectional schematic diagram of a typical semiconductor device according to some embodiments.

FIG. 5 illustrates a flow chart of methods according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

It must be noted that as used herein and in the claims, the singular forms “a,” “an,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Where the modifier “about” or “approximately” is used, the stated quantity can vary by up to 10%. Where the modifier “substantially equal to” or “substantially the same” is used, the two quantities may vary from each other by no more than 5%.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

The term “substrate” as used herein may refer to any workpiece on which formation or treatment of material layers is desired. Substrates may include, without limitation, silicon, germanium, silicon-germanium alloys, gallium arsenide, indium gallium arsenide, indium gallium antimonide, silica, sapphire, zinc oxide, silicon carbide, aluminum nitride, Spinel, coated silicon, silicon on oxide, silicon carbide on oxide, glass, gallium nitride, indium nitride, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter.

Those skilled in the art will appreciate that each of the layers discussed herein may be formed using any common formation technique such as atomic layer deposition (ALD), plasma enhanced atomic layer deposition (PE-ALD), atomic vapor deposition (AVD), ultraviolet assisted atomic layer deposition (UV-ALD), chemical vapor deposition (CVD), plasma enhanced chemical vapor deposition (PECVD), or physical vapor deposition (PVD). Generally, because of the complex morphology of the device interconnect structure, ALD, PE-ALD, AVD, or CVD are preferred methods of formation. However, any of these techniques are suitable for forming each of the various layers discussed herein. Those skilled in the art will appreciate that the teachings described herein are not limited by the technology used for the deposition process.

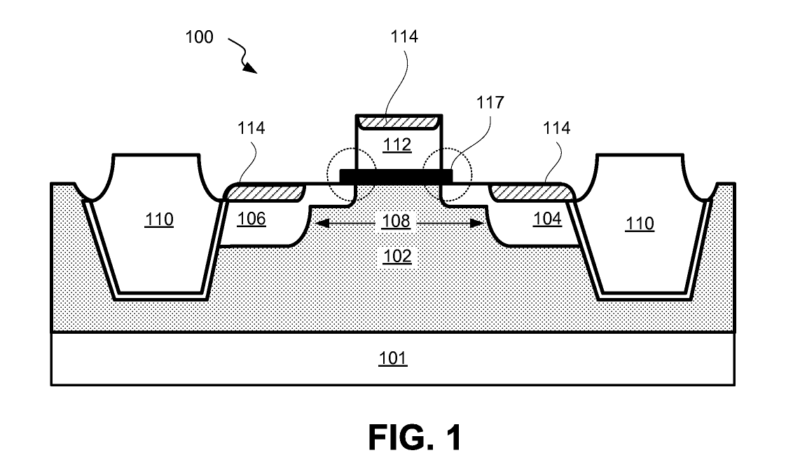

A brief description of generic semiconductor device examples is presented below to provide better understanding of various processes. Specifically, FIG. 1 illustrates a schematic representation of substrate portions including MOS device, 100. The references below are made to positive metal-oxide semiconductor (PMOS) devices but other types of MOS devices can be used in the described processes and will be understood by one having ordinary skill in the art. As will be discussed below, some of the steps required to manufacture the generic device illustrated in FIG. 1 are not needed in some embodiments. MOS device 100 includes a p-doped substrate, 101, and an n-doped well, 102, disposed within substrate, 101. Substrate, 101, is typically a part of an overall wafer that may include other devices. Some of these devices may include silicon nitride, silicon oxide, polysilicon, or titanium nitride structures. P-doped substrate, 101, may include any suitable p-type dopants, such as boron and indium, and may be formed by any suitable technique. N-doped well, 102, may include any suitable n-type dopants, such as phosphorus and arsenic, and may be formed by any suitable technique. For example, n-doped well, 102, may be formed by doping substrate, 101, by ion implantation, for example.

MOS device, 100, also includes a conductive gate electrode, 112, that is separated from n-doped well, 102, by gate dielectric, 117. Gate electrode, 112, may include any suitable conductive material. In some embodiments, gate electrode, 112, may comprise polysilicon. In some embodiments, gate electrode, 112, may include polysilicon doped with a p-type dopant, such as boron. Gate dielectric, 117, is formed from a high-κ material (e.g. hafnium oxide). Other dielectric materials include zirconium oxide or aluminum oxide. Typically, a semiconductor material with high mobility such as germanium or a silicon-germanium alloy (not shown) is formed beneath the gate dielectric.

MOS device, 100, also includes p-doped source region, 104, and drain region, 106, (or simply the source and drain) disposed in n-doped well, 102. Source, 104, and drain, 106, are located on each side of gate electrode, 112, forming channel, 108, within n-doped well, 102. Source, 104, and drain, 106, may include a p-type dopant, such as boron (or e.g. gallium for germanium). Source, 104, and drain, 106, may be formed by ion implantation. After forming source, 104, and drain, 106, MOS device, 100, may be subjected to an annealing and/or thermal activation process.

In some embodiments, source, 104, drain, 106, and gate electrode, 112, are covered with a layer of self-aligned silicide portions, 114, which may be also referred to as salicide portions or simply salicides. For example, a layer of cobalt may be deposited as a blanket layer and then thermally treated to form these silicide portions, 114. Other suitable materials include nickel and other refractory metals, such as tungsten, titanium, platinum, and palladium. After forming the blanket layer from the suitable metal, the layer is subjected to rapid thermal process (RTP) to react the metal with silicon contained within gate electrode, 112, as well as within source, 104, and drain, 106, to form a metal silicide. The RTP process may be performed at 700° C. to 1000° C.

MOS device, 100, may also include shallow trench isolation (STI) structures, 110, disposed on both sides of source, 104, and drain, 106. STI structures, 110, may include liners formed on the side and bottom walls by, for example, thermal oxidation of silicon of n-doped well, 102. The main body of STI structures is formed by filling a trench within n-doped well, 102, with a dielectric material, such as silicon oxide. Silicon oxide may be filled using high density plasma (HDP) deposition process.

As shown in FIG. 1, gate dielectric, 117, may protrude beyond gate electrode, 112. As such, gate dielectric, 117, may need to be partially etched such that it does not extend past electrode, 112, and does not interfere with subsequent formation of liners and spacers on sidewalls of gate electrode, 112.

In some embodiments, the gate dielectric, 117, and/or the gate electrode, 112, may receive a surface plasma treatment to improve the performance of the device.

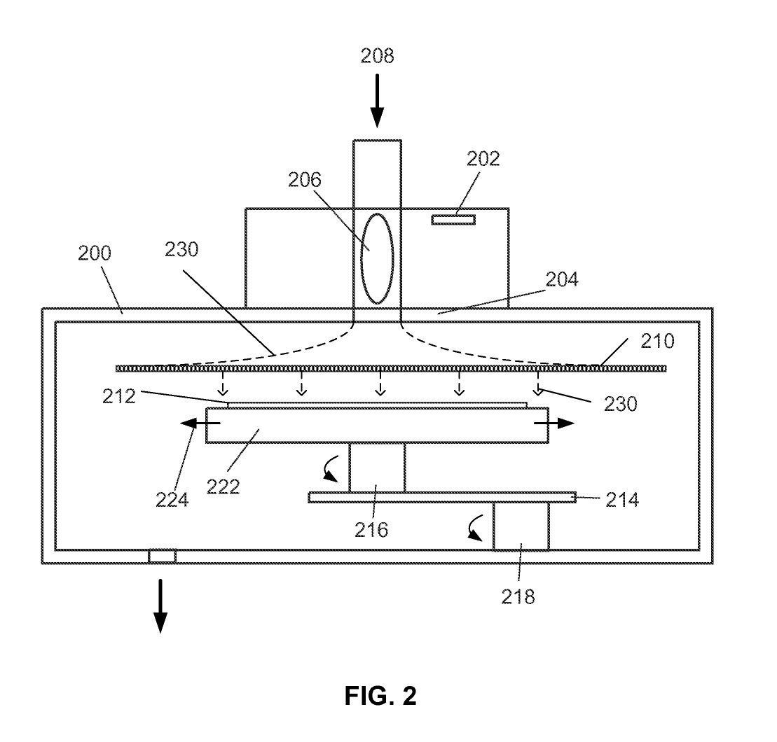

FIG. 2 illustrates the overall layout of some embodiments of a system enabling processing (e.g. PECVD) using a remote plasma source. A process chamber, 200, is provided. A remote plasma source, 202, is mounted on a chamber lid, 204, either directly as illustrated or through a short flange. The plasma, 206, is entrained into a central gas flow, 208, which is directed toward a showerhead, 210. The showerhead is disposed within the processing chamber between the remote plasma source and the substrate and is in close proximity to the substrate, 212. The showerhead is operable to provide exposure of reactive species from the remote plasma source to deposit materials on the substrate. A substrate positioning system, 214, can position the substrate, 212, directly under the showerhead, 210. As illustrated in FIG. 2, the substrate positioning system can provide two displaced axes of rotation, 216, and 218. The two-axis rotation configuration illustrated can provide 360° of rotation for the upper rotation (providing an angular coordinate) and 60° of rotation for the lower axis (approximating a radial coordinate) to provide all possible substrate positions. Alternatively, other positioning systems such as X-Y translators can also be used. In addition, substrate support, 222, may move in a vertical direction. It should be appreciated that the rotation and movement in the vertical direction may be achieved through known drive mechanisms which include magnetic drives, linear drives, worm screws, lead screws, a differentially pumped rotary feed through drive, etc.

The substrate support, 222, can include a substrate heater (e.g., resistive or inductive) and can be sized to be larger than the largest substrate to be processed. Substrate temperatures for most PECVD applications are less than 700 C, although any suitable heater power and range of temperature control. The substrate support, 222, can also be configured to provide a gas purge flow, 224, for example from the edges of the support, using argon, helium, or any other gas that is not reactive under the process conditions.

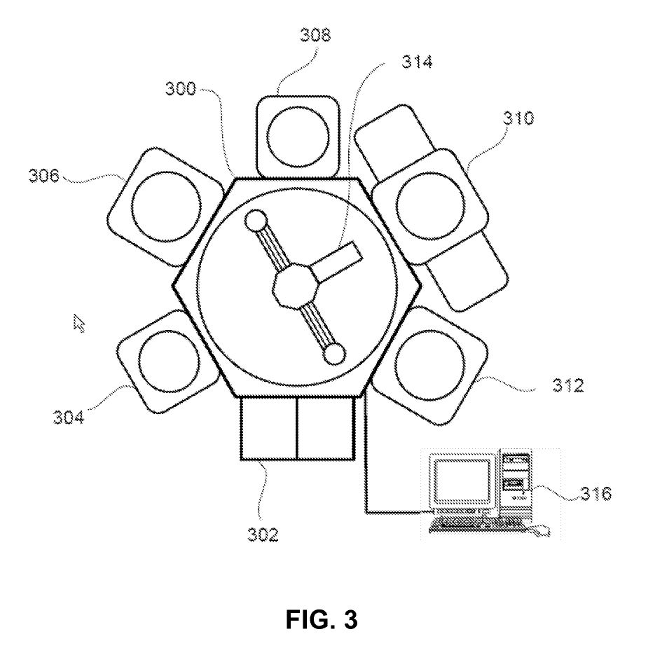

FIG. 3 is a simplified schematic diagram illustrating an integrated processing system in accordance with some embodiments of the invention. The processing system includes a frame, 300, supporting a plurality of processing modules. It will be appreciated that frame, 300, may be a unitary frame in accordance with some embodiments. In some embodiments, the environment within frame, 300, is controlled. A load lock, 302, provides access into the plurality of modules of the processing system. A robot, 314, provides for the movement of substrates (and masks) between the modules and for the movement into and out of the load lock, 302. Modules, 304-312, may be any set of modules and preferably include one or more processing modules. For example, module, 304, may be an orientation/degassing module, module, 306, may be a clean module, either plasma or non-plasma based, modules, 308, and/or 310, may be dual purpose modules. Module, 312, may provide conventional clean or degas as necessary.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device, 316, may control the processes of the processing system. Further details of one possible processing system are described in U.S. application Ser. Nos. 11/672,478 and 11/672,473, the entire disclosures of which are herein incorporated by reference. In a processing system, a plurality of methods may be employed to deposit material upon a substrate.

Plasmas are widely used for a variety of treatment and layer deposition tasks in semiconductor fabrication. These applications include subtractive processes such as wafer precleaning, contaminant removal, native oxide removal, photoresist removal, additive processes such as plasma enhanced deposition, and treatment processes such as oxidation, nitridation, or hydridation of a layer both during and after formation. “Remote” plasma sources are frequently used, where the plasma is located at some distance from the surface to be treated or substrate on which a layer is to be formed. The distance allows some adjusting of the charged particles in the plasma. For example, the density of ions and electrons can be adjusted by distance, the electrons and ions can be removed from the generated plasma using suitable electrode configurations such as a grounded metal showerhead, so that, for example, only atomic radicals and molecule radicals (but not ions) reach the substrate.

The plasma generator for a remote plasma source can use any known means of coupling energy into atoms or molecules to ionize them and create a plasma. The energy source can be, for example, electromagnetic energy such as microwaves, radio frequency energy, or lasers.

In some embodiments, many of the problems that arise in manufacturing transistor gate stacks can be solved by inverting the order of deposition and building the devices upside down relative to conventional fabrication methods. As discussed previously, prior approaches start with the channel semiconductor, typically requiring a buffer layer to allow the growth of reasonably low-defect semiconductor channel structures of high-mobility semiconductors such as germanium on a silicon substrate. After the semiconductor channel is formed, the gate stack is completed by depositing (in order) an interface layer, a dielectric layer (typically comprising a high-κ dielectric), and a gate electrode (which may itself comprise two or more layers).

In some embodiment, this deposition order is reversed by depositing the gate electrode first and depositing the semiconductor channel last. This “channel-last” fabrication sequence provides fundamentally different device fabrication challenges, allows the process to be optimized in a more controlled fashion, and reduces the required size (length and thickness) for the semiconductor channel. In the prior approaches, the semiconductor channel is formed between the substrate and the gate dielectric; thus the substrate-channel interface and the channel-gate dielectric interface are a major source of defects. In contrast, by using the channel-last fabrication sequence, there is no substrate-channel interface, and that particular source of lattice defects is eliminated. Further, since the gate dielectric is more chemically and thermally stable than the semiconductor channel, a larger process window is available for surface preparation of the dielectric to enable channel material deposition. Because the dielectric of the gate oxide can be very thin, it is possible to form channels on top of the gate oxide that have few threading defects, and lattice strain parameters can be engineered using chemical composition of the gate dielectric, interface layers, and surface treatments.

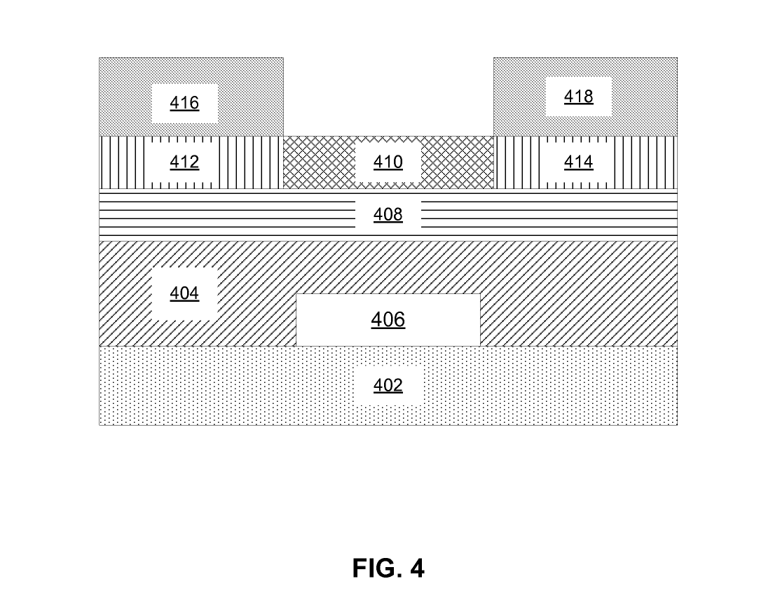

FIG. 4 illustrates a cross-sectional schematic diagram of a typical semiconductor device according to some embodiments. In some embodiments, the gate electrode 406 (a first layer) can be formed first, either directly on the substrate 402 or optionally on a pre-deposited buffer layer (not shown). The gate electrode can be deposited as a single layer or multiple layers, typically comprising one or more metals. A dielectric 404 (a second layer) can then be formed. Any suitable dielectric material can be used. In some embodiments, the dielectric material can be, for example, high-κ dielectric materials such as oxides of aluminum, dysprosium, gadolinium, hafnium, lanthanum, yttrium, zirconium, or combinations thereof. High-κ dielectrics can alternatively include one or more of silicon oxynitride, silicon nitride, tantalum oxide, titanium oxide, zirconium oxide, hafnium oxide, aluminum oxide, lanthanum oxide, yttrium oxide, yttrium aluminate, lanthanum aluminate, lanthanum silicate, yttrium silicate, hafnium silicate, zirconium silicate, and doped alloys, undoped alloys, mixtures, and/or multilayers thereof. A typical high-κ dielectric material is hafnium oxide. High-κ dielectric materials typically have κ-values greater than about 7.

Accordingly, other dielectric materials such as oxides of silicon and aluminum can also be used. The dielectric thickness is typically small, but may vary according to the material selected, the desired transistor performance characteristics, and the lateral feature dimensions. The thickness is typically less than that of the gate electrode and less than the width of the gate electrode. Also as shown in FIG. 4, the dielectric need not be patterned to match the dimensions of the gate electrode, but can extend generally into adjacent regions to passivate the substrate or other structures and/or to planarize the surface in preparation for semiconductor deposition.

An optional interface layer (a fifth layer, not shown) can be deposited on the dielectric 404 prior to deposition of the semiconductor. In some embodiments, the interface layer serves as a diffusion barrier to prevent atomic migration between the channel semiconductor and the gate dielectric. Additionally, the interface layer can be used to control strain in the semiconductor channel; strain in the semiconductor channel (e.g. silicon and/or silicon-germanium alloys) is used to increase mobility. An exemplary interface layer typically comprises less than 2 nm of silicon oxide, although other materials are possible.

A thin layer of semiconductor material 408 (a third layer) can then be formed on the gate dielectric 404 to function as a channel. The semiconductor material 408 can be a single-crystalline semiconductor layer of sufficient thickness to provide the channel functionality. Thickness can vary according to material selection, feature size, and desired performance, but typically the channel can be very thin, for example, less than 10 nm, and in some embodiments, between about 1.0 nm and about 1.5 nm. Various semiconductors can be used, for example germanium, silicon germanium alloys, intrinsic graphene, or III-V semiconductors such as gallium arsenide, which are all examples of semiconductors used instead of silicon when higher carrier mobility is required, although the invention is not limited to any particular semiconductor. The semiconductor can also be lightly doped using conventional dopants. Such dopants are generally present in very small amounts (0.01 atomic % or less).

In some embodiments, a thin layer 410 (a sixth layer) can advantageously be formed as shown on the surface of the channel semiconductor layer 408 to function as a passivation layer. In some embodiments, layer 410 is deposited as an amorphous carbon layer using a PECVD technique. Typical precursors used for the PECVD deposition of the amorphous carbon layer include methane and hydrogen. The reducing atmosphere of the deposition process may also act to remove interfacial oxide materials that may have formed on the surface of the channel. The amorphous carbon may be converted to graphene in regions under the source and drain contacts (layers 412 and 414) during a subsequent heating step. The conversion to graphene may be catalyzed by the metal materials present in the source and drain contact layers. Layer 410 will remain as amorphous carbon in the regions between the source and drain since there is no metal to catalyze the conversion to graphene.

Lastly, the source 416 and drain 418 are formed as a fourth layer as shown. In some embodiments, the source and drain comprise one or more conductive materials, for example one or more metals, and function as electrodes. The fourth layer is formed on the semiconductor layer 408 (or on the passivation layer 410). The spacing between the source and drain defines the length of the channel which is typically set to be approximately equal to the width of the gate electrode as illustrated in FIG. 4.

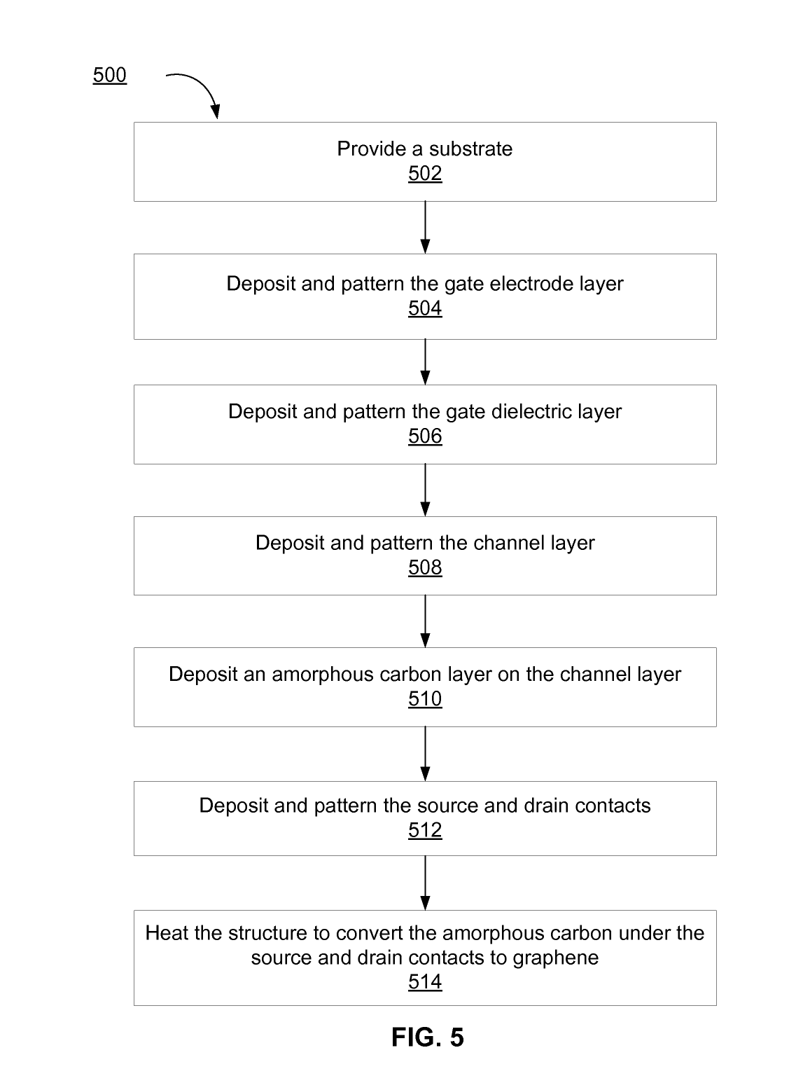

FIG. 5 illustrates a flow chart of methods according to some embodiments. In step 502, a substrate is provided. As discussed previously, the substrate may include, without limitation, silicon, germanium, silicon-germanium alloys, gallium arsenide, indium gallium arsenide, indium gallium antimonide, silica, silicon carbide, aluminum nitride, coated silicon, silicon on oxide, silicon carbide on oxide, gallium nitride, indium nitride, etc. The semiconductor wafer shapes and sizes can vary and include commonly used round wafers of 50 mm, 100 mm, 150 mm, 200 mm, 300 mm, or 450 mm in diameter.

In step 504, a gate electrode layer (e.g. layer 406) is deposited and patterned on the substrate. Typical gate electrode materials include doped polysilicon, titanium nitride, tantalum nitride, conductive metal silicides, and conductive metal salicides, among others.

In step 506, a gate dielectric layer (e.g. layer 404) is deposited and patterned above the substrate and the gate electrode layer. As discussed previously, the gate dielectric layer is typically a high-κ dielectric material such as oxides of aluminum, dysprosium, gadolinium, hafnium, lanthanum, yttrium, zirconium, or combinations thereof. High-κ dielectrics that can be used are not particularly limiting, and can include one or more of silicon oxynitride, silicon nitride, tantalum oxide, titanium oxide, zirconium oxide, hafnium oxide, aluminum oxide, lanthanum oxide, yttrium oxide, yttrium aluminate, lanthanum aluminate, lanthanum silicate, yttrium silicate, hafnium silicate, zirconium silicate, and doped alloys, undoped alloys, mixtures, and/or multilayers thereof. A typical high-κ dielectric material is hafnium oxide.

In step 508, a semiconductor channel layer (e.g. layer 408) is deposited and patterned above the gate dielectric layer. The semiconductor material 408 can be a single-crystalline semiconductor layer of sufficient thickness to provide the channel functionality. Thickness can vary according to material selection, feature size, and desired performance, but typically the channel can be very thin, for example, less than 10 nm, and in some embodiments, between about 1.0 nm and about 1.5 nm. Various semiconductors can be used, for example germanium, silicon germanium alloys, graphene, or III-V semiconductors such as gallium arsenide, which are all examples of semiconductors used instead of silicon when higher carrier mobility is required, although the invention is not limited to any particular semiconductor. The semiconductor can also be lightly doped using conventional dopants. Such dopants are generally present in very small amounts (0.01 atomic % or less).

In step 510, an amorphous carbon layer (e.g. layer 410) is deposited above the semiconductor channel layer. The amorphous carbon layer may be deposited using a PECVD process wherein methane and hydrogen are used as precursor gases. The amorphous carbon layer may be converted to graphene in some regions of the device as will be described below.

The technique described herein eliminates the need to transfer the graphene to the dielectric surface from a metallic substrate as is conventionally performed. In the method, amorphous carbon, containing some amount of hydrogen, is deposited as a thin film on the semiconductor channel layer. In some embodiments, amorphous carbon refers to carbon having a maximum ratio of sp³ to sp² bonds of 50% and hydrogen, nitrogen, or oxygen atoms may be bonded to the sp³ carbons. As described below, the techniques convert the sp³ bonds to sp² bonds through a relatively low temperature process that is amenable to conventional semiconductor processing techniques. A metal, (e.g., iron, cobalt, nickel, or others), is deposited over the layer of amorphous carbon. The deposited layer is patterned. The substrate in then heated. In some embodiments, the heating occurs at a temperature between about 120° C. to about 500° C. In some embodiments, the heating occurs at a temperature between about 120° C. to about 1200° C. In addition, the temperature ramp rates can range from about 10° C./min to 40° C./min and heating times can range from between about 1 minute to about 60 minutes. The heating converts the sp³ carbon bonds of the amorphous carbon layer immediately under the transition metal to sp² carbon bonds through a metal catalyzed mechanism. It should be appreciated that graphene may refer to domains of sp² bonded carbon with single or multiple graphene layers, with the size of the individual domains determined by the properties of the metal film. The number of graphene layers depends on the thickness of the amorphous carbon film, the metal film thickness, and heating conditions. Further details of the metal catalyzed conversion of amorphous carbon to graphene are discussed in U.S. patent application Ser. No. 13/315,524, filed on Dec. 9, 2011, now U.S. Pat. No. 8,361,813, which is herein incorporated by reference for all purposes.

In some embodiments, the amorphous carbon layer is formed by using a PECVD process. For example, a plasma generated during a PECVD process includes hydrogen gas and methane. In some embodiments, when the amorphous carbon layer(s) are formed, the plasma power may be in the range of 500-1900 Watts and the plasma frequency may be in the range of 50 KHz to 2 GHz. In addition, the pressure within the processing chamber may be in the range of 0.1-5 Torr. In some embodiments, the temperature of the substrate when forming the amorphous carbon layer(s) may be in the range of 25° C. to 500° C.

In step 512, source and drain layers (e.g. layers 416 and 418) are deposited and patterned above the amorphous carbon layer. In some embodiments, the source and drain comprise one or more conductive materials, for example one or more metals and function as electrodes. In some embodiments, the source and drain include one or more conductive materials such as nickel, cobalt, nickel alloys, cobalt alloys, and the like. In some embodiments, the source and drain include multiple layers of the conductive materials.

In step 514, the structure is heated to a temperature of between about 120° C. to about 500° C. As discussed previously, the metal materials in the source and drain layers catalyze the conversion of the amorphous carbon layers under these layers to graphene (e.g. layers 412 and 414). It should be noted that the portions of the amorphous layer that are not covered by the source and drain layers will remain as an amorphous carbon layer after the heating (e.g. layer 410).

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method comprising:
depositing a semiconductor channel layer above a surface of a substrate;
depositing an amorphous carbon layer on the semiconductor channel layer;
depositing source and drain layers on the amorphous carbon layer; and
heating the substrate.

2. The method of claim 1 wherein the amorphous carbon layer is formed using a plasma enhanced chemical vapor deposition (PECVD) process.

3. The method of claim 2 wherein gases used in the PECVD process comprise hydrogen and methane.

4. The method of claim 2 wherein a plasma power used in the PECVD process is between 500 watts and 1900 watts.

5. The method of claim 2 wherein a plasma frequency used in the PECVD process is between 50 KHz and 2 GHz.

6. The method of claim 2 wherein a temperature of the substrate during the PECVD process is between 25° C. and 500° C.

7. The method of claim 1 wherein the heating occurs at a temperature between 120° C. and 500° C.

8. The method of claim 1 wherein the heating occurs for a time between 1 minute and 60 minutes.

9. The method of claim 1 wherein the source and drain layers comprise at least one of nickel, cobalt, a nickel alloy, or a cobalt alloy.

10. The method of claim 1 further comprising patterning the source and drain layers before the heating.

11. The method of claim 1 further comprising depositing and patterning a gate electrode layer before depositing the semiconductor channel layer.

12. The method of claim 11 wherein the gate electrode layer comprises at least one of doped polysilicon, titanium nitride, tantalum nitride, a conductive metal silicide, or a conductive metal salicide.

13. The method of claim 1 further comprising depositing and patterning a gate dielectric layer before depositing the semiconductor channel layer.

14. The method of claim 13 wherein the gate dielectric layer comprises a high-κ material.

15. The method of claim 14 wherein the gate dielectric layer comprises at least one of silicon oxynitride, silicon nitride, tantalum oxide, titanium oxide, zirconium oxide, hafnium oxide, aluminum oxide, lanthanum oxide, yttrium oxide, yttrium aluminate, lanthanum aluminate, lanthanum silicate, yttrium silicate, hafnium silicate, or zirconium silicate.

16. The method of claim 1 wherein the semiconductor channel layer comprises one of germanium, silicon germanium alloys, graphene, or gallium arsenide.

17. A semiconductor device comprising:
a semiconductor channel layer formed above a surface of a substrate;
an carbon layer formed on the semiconductor channel layer; and
source and drain layers formed on a first part of the carbon layer, wherein the first part of the carbon layer comprises graphene.

18. The semiconductor device of claim 17 wherein the source and drain layers comprise at least one of nickel, cobalt, a nickel alloy, or a cobalt alloy.

19. The semiconductor device of claim 17 wherein the semiconductor channel layer comprises one of germanium, silicon germanium alloys, graphene, or gallium arsenide.

20. The semiconductor device of claim 17 further comprising a gate dielectric layer, wherein the gate dielectric layer comprises at least one of silicon oxynitride, silicon nitride, tantalum oxide, titanium oxide, zirconium oxide, hafnium oxide, aluminum oxide, lanthanum oxide, yttrium oxide, yttrium aluminate, lanthanum aluminate, lanthanum silicate, yttrium silicate, hafnium silicate, or zirconium silicate.
